(19) United States
(12) Patent Application Publication
(10) Pub. No.: US 2013/0269767 A1
(43) Pub. Date: Oct. 17, 2013

(54) METHOD OF COATING A SUBSTRATE FOR MANUFACTURING A SOLAR CELL

(71) Applicants: Oliver Kluth, Walenstadt (CH); Onur Caglar, Thalwil (CH); Losio Paolo, Pfaffikon (CH); Stephanie Goldbach-As-Chemann, Sevelen (CH)

(72) Inventors: Oliver Kluth, Walenstadt (CH); Onur Caglar, Thalwil (CH); Losio Paolo, Pfaffikon (CH); Stephanie Goldbach-As-Chemann, Sevelen (CH)

(73) Assignee: TEL SOLAR AG, Trubbach (CH)

(21) Appl. No.: 13/819,949

(22) PCT Filed: Sep. 1, 2011
(86) PCT No.: PCT/EP2011/065134

§ 371 Date: Jul. 2, 2013

Related U.S. Application Data
(60) Provisional application No. 61/379,917, filed on Sep. 3, 2010.

(51) Int. Cl. H01L 31/18; H01L 31/0224

(52) U.S. Cl. CPC H01L 31/1884; H01L 31/022425
USPC 136/256; 438/69

(57) ABSTRACT

The invention relates to a method of coating a substrate for manufacturing a solar cell in a deposition environment, the method comprising the steps of: a) Depositing a first zinc oxide layer onto a substrate. Reducing a zinc precursor content in the deposition environment, c) Treating the first zinc oxide layer with a mixture of diborane and water to form a plurality of coating seeds on the surface of the first zinc oxide layer, and d) Depositing a second zinc oxide layer onto the first zinc oxide layer. The method according to the invention allows improving the material quality of silicon layers which may later be grown on such a substrate. Additionally, the light scattering and subsequent light trapping in a respective solar cell may be enhanced by a method according to the invention. The present invention further relates to a solar cell being manufactured according to the invention.

### TECHNICAL FIELD

This invention refers to a method of coating a substrate for manufacturing a solar cell. The invention particularly refers to coating a substrate with a transparent conductive oxide layer, especially for modifying the surface morphology of a transparent conductive front electrode forming part of a silicon thin film solar cell. The morphology modification is obtained by modifying the growth process of the transparent conductive layer. The method according to the invention allows improving the material quality of silicon layers which may later be grown on such a substrate. Additionally, the light scattering and subsequent light trapping in a respective solar cell may be enhanced by a method according to the invention.

### BACKGROUND ART

Photovoltaic devices, photoelectric conversion devices or solar cells are devices which convert light, especially sunlight into direct current (DC) electrical power. The solar cell structure, i.e. the layer sequence responsible for or capable of the photovoltaic effect is deposited in thin layers on the substrate. This deposition, or coating, respectively, may take place under atmospheric or vacuum conditions. Deposition techniques, for example for forming a front electrode, are widely known in the art, such as physical vapour deposition (PVD), chemical vapour deposition (CVD), plasma enhanced chemical vapour deposition (PECVD), atmospheric pressure chemical vapour deposition (APCVD), and furthermore, all being used in semiconductor technology.

With respect to the front electrode coated on a substrate, there are different features which preferably should be fulfilled. In detail, front electrodes, such as TCO layers (transparent and conductive metal oxide), should preferably be optically transparent, electrically conductive, should comprise a rough surface morphology which introduces light scattering and an optimal morphology for growth of silicon layers and should comprise an optimal refractive index to minimize reflections.

The parameters which may allow achieving these requirements are, however, coupled. Usually optimizing one aspect is done at the cost of deteriorating another aspect. A simple example is roughness: the surface roughness can be easily increased by increasing the thickness of a TCO layer formed of zinc oxide (ZnO), for example; light scattering is improved but silicon layers coated thereon will then include a large amount of defects induced by the roughness.

Especially two methods have been established so far to realize suitable front electrodes for thin film solar cells. The first method comprises the growth of transparent and conductive metal oxides TCO with naturally grown rough surface morphologies by chemical vapour deposition techniques, such as atmospheric pressure CVD of tin oxide (SnO₂), or low pressure CVD of zinc oxide, for example.

A second method comprises physical vapour deposition of zinc oxide being followed by a post-treatment by wet chemical etching in order to achieve a rough light scattering surface morphology. This procedure may involve washing the TCO coated substrates, such as glasses, with a diluted boric acid solution or other preferably diluted acids or bases.

These two methods described above are currently used for large area mass production of thin film solar modules, in particular for silicon thin film solar cells.

It is furthermore well know that in p-i-n-silicium thin film solar cell devices the surface morphology of the front electrode strongly influences the light trapping and hence also the current generation. In single junction cells, having only one p-i-n-junction, the surface features of the transparent and conductive metal oxide can be optimized for the spectrally dependent absorption characteristic of the single absorber layer. For example, in case of single junction silicon thin film solar cells with amorphous silicon (a-Si:H) the absorber layer may be optimized via chemical vapour deposition of tin oxide and low pressure chemical vapour deposition of zinc oxide. Such coated substrates are already commercially available. With respect to microcrystalline silicon (pc-Si:H) single junction p-i-n solar cells, the highest efficiencies have so far been achieved by using chemically post treated physical vapour deposition of zinc oxide, while layers of “as grown” rough transparent and conductive metal oxides based on chemical vapour deposition of zinc oxide and tin oxide turned out to be less effective.

Detailed studies of μc-Si:H single junction p-i-n solar cells on naturally rough grown zinc oxide being coated by low pressure chemical vapour deposition, where the surface morphology was modified by a post-treatment plasma etching step, revealed that the as grown pyramidal like surface features lead to more defect rich pc-Si:H absorber material while a craterlike structure of the post treated zinc oxide being coated by low pressure chemical vapour deposition helped to reduce these defects leading also to a substantially improved solar cell performance and excellent high efficiencies. These studies further disclosed that a prolonged post treatment, such as a treatment for more than 80 minutes, leads to craterlike surface features which are quite comparable to the surface features of chemically post treated zinc oxide being coated by physical vapour deposition.

This is visualized in FIG. 1 in which zinc oxide layers are shown as grown (left image), after 40 minutes of treatment (middle image) and after 80 minutes of treatment (right image). However, there was also a drop in solar cell current observed for extended plasma treatment of zinc oxide being coated by low pressure chemical vapour deposition. This is shown in FIG. 2. In detail, in the left image, the voltage (V) and the fill factor (FF) are applied against the treatment time. The fill factor is particularly a value stating the degree according to which the solar cell may collect the charge carriers provided by light. In the middle image, the current, especially the short circuit current (I_{sc}) and the current at a reverse voltage (Iᵣₑᵥ) at a reverse current of −2V. Additionally, in the right image, the efficiency (η) is applied against the treatment time. This may demonstrate that the craterlike surface helps to support the silicon growth but is not the ideal surface morphology for optimized light trapping. Moreover, in a tandem device where an a-Si:H based cell is combined with μc-Si:H cell, the requirements of both cells are quite difficult to fulfil with a front contact optimized either for a-Si:H or μc-Si:H single junction cells (M. Python et al. Journal of non-crystalline solids, vol. 354, 2008, p. 2258-2262).

Indeed the publications available for silicium thin film tandem cells on the different commercial available substrates show clearly a limitation either in the light trapping or in the growth of the silicon layers depending on the kind of substrate used in these tandem solar cells.

An ideal surface morphology for the light trapping in a tandem device should include small and big features. Small features or roughness on a short scale can scatter light with a short wavelength effectively, which is essential for an a-Si:H device. For μc-Si:H of a bottom cell, however, the scattering of long wavelength light is more important. Therefore, the surface should also include bigger structures.

When a zinc oxide layer is grown with low pressure chemical vapour deposition, it starts with small crystallites. As the layer becomes thicker, some crystallites are overgrown by other bigger ones and, therefore, the surface features become larger. In effect, the surface of a thin zinc oxide layer is more suitable for light trapping in a a-Si:H device and a thick layer better for μc-Si:H. A zinc oxide surface grown by usual methods shows a distribution of feature sizes which does not completely cover the useful range for tandem devices.

A possible solution to extend this range of feature sizes involves growing a series of layers with different properties. Typically this can be achieved by modifying the doping of each layer. However, experiments have shown that zinc oxide growth is not influenced by changes in doping concentration (“compositions”). Crystallites of the second layer continue to enlarge the crystallites of the first layer even if the composition is changed.

Another option is to insert a layer of a different material into the zinc oxide layer. In this case, growth restarts at the new material and the resulting surface has big features overgrown by small zinc oxide crystallites.

A completely different solution involves the use of a substrate surface that already has some corrugations at a big scale, such as structured glass, for example.

Both methods however involve additional steps in the production process. This leads to a much longer process time and extra material costs which lead to a higher cost of ownership of manufacturing systems (COO).

Known from US2008/0196761 is a process comprising the step of introducing multilayer TCO with multiscale structures. According to this document, this is realized by using two approaches: either two or more different TCO materials are grown sequentially, or thin interlayers of a different material are added between two layers of the same material

EP 2 084 752 A9 uses two different deposition methods. In detail, zinc oxide coated by low pressure chemical vapour deposition is followed by a deposition of zinc oxide by physical vapour deposition.

EP 0 940 857 B1 uses two different TCO materials. Apart from that, the cells are “inverted” which means that light is not coming from the glass substrate side.

Not all of the above mentioned requirements for the front electrode are already fulfilled in an ideal manner according to the processes known from the state of the art.

### Disclosure of Invention

Therefore, it is an object of the present invention to overcome at least one before described disadvantages of prior art, i.e. to provide a method of coating a substrate for manufacturing a solar cell having at least one of improved light scattering, light trapping, reduction of reflection losses and material quality of silicon layers grown on the electrode.

This object is achieved by the independent claims. Advantageous embodiments are detailed in the dependent claims.

Particularly, the object is achieved by a method of coating a substrate in a deposition environment for manufacturing a solar cell, the method comprising the steps of:

a) Depositing a first zinc oxide layer onto a substrate,

b) Reducing a zinc precursor content in the deposition environment,

c) Treating the first zinc oxide layer with a mixture of diborane and water to form a plurality of coating seeds on the surface of the first zinc oxide layer, and

d) Depositing a second zinc oxide layer onto the first zinc oxide layer.

The present invention helps to further exploit the remaining potential particularly in the improvement of light scattering, light trapping, reduction of reflection losses as well as the material quality of thin film silicon layers grown on these substrates. Furthermore, a novel approach is provided to overcome the problems known in the art and develops a TCO front electrode for tandem solar cells which combines an improved light trapping for both a-si:H top and μc-Si:H bottom cell in a tandem device as well as improved growth conditions resulting in less defects in the silicon absorber layers.

The present invention is based on the central idea that by treating the first zinc oxide layer with a mixture of diborane and water not only a further layer is simply grown on the first layer. Contrary thereto, the formation of a new seeding layer is provided. Consequently, with respect to the second layer, the growth of zinc oxide is restarted from new seeds.

The present inventors have found that simply changing the composition (e.g. doping) or simply interrupting the layer growth is not a sufficiently effective measure to produce new seeds for layer growth. Contrary thereto, the method according to the present invention provides a new treatment of the surface which enables new seeding.

One main goal achieved by this method, restarting the second layer by new seeds, is particularly to achieve haze values as high as possible without increasing the surface roughness to a level which disturbs the subsequent growth of silicon layers.

This invention overcomes the fundamental problem of restarting zinc oxide growth by only using a simple procedure within the usual process without having to remove the substrate from the process chamber, like known in the state of the art.

Additionally, several zinc oxide layers are grown one after the other. Each layer may have a specific composition (doping, H₂O/DEZ ratio etc.) which allows tuning its properties independently of the previous layer. As a consequence of the method according to the invention, zinc oxide growth will restart independently of the underlying zinc oxide structures.

The solution according to the invention is furthermore simpler, faster and less expensive than the solutions presented in the prior art

The suggested treatment procedure requires only a modification of previously known process steps addressing process gases, and eventually temperatures and pressures.

Another aspect of optical optimization includes the reduction of reflection at the interface between TCO and silicon layers. Reflections arise when light travelling in a material encounters a material with a different refractive index. In the simplified case of a flat interface the reflection coefficient for light travelling from a material with refractive index n1 to a material with refractive index n2 is R=(n1−n2)̂2/(n1+n2)̂2. Reflection losses depend on the difference between the refractive index of the materials. Using rough interfaces (=interfaces which are not flat because one surface is composed by structures like pyramids having a lateral size comparable or smaller than the wavelength of light) allows to partially compensate for the reflection losses because the incoming light sees an average refractive index. The average refractive index arises from mixing two materials in a region smaller than the wavelength of light. However, it is in principle possible according to the invention to even further reduce the reflection losses by optimizing the refractive index at the interfaces. The refractive index of a conductive material is influenced by its conductivity. Increasing the conductivity allows reducing the refractive index.

The method according to the invention comprising providing new seeds for the growth of the second zinc oxide layer thus allows to simply prepare multilayer zinc oxide contacts and to gain more degrees of freedom for optimizing the complete stack. It is then possible to optimize conductivity, roughness, haze, reflection losses and surface morphology independently from another.

The term “substrate” in sense of the current invention particularly comprises a component, part or workpiece to be coated with a transparent and conductive metal oxide layer in order to generate an electrode, such as a front electrode of a solar cell. A substrate includes but is not limited to flat-, plate-shaped part having rectangular, square or circular shape. Preferably, the substrate is suitable for manufacturing a thin film solar cell and comprises a float glass, a security glass and/or a quartz glass. More preferably, the substrate is provided as an essentially, most preferably completely flat substrate having a planar surface of a size≧1 m², such as a thin glass plate. However, the method according to the invention may alternatively or additionally be used in order to generate a back electrode of a solar cell. In this case, the substrate may comprise a semiconductor layer.

The term “depositing”, comprises in sense of the present invention all processes being able to coat a compound on a surface. The term depositing thereby includes but is not limited to chemical vapour deposition or physical vapour deposition, for example. With respect to chemical vapour deposition, for example, a usually liquid or gaseous precursor material, the gas, is being fed to a process system, where a thermal reaction of the precursor results in deposition of the layer. Often, DEZ, diethyl zinc, is used as precursor material for the production of zinc oxide TCO layers in a vacuum processing system using low pressure CVD, LPCVD.

The term “TCO” stands for transparent conductive oxide, i.e. TCO layers are transparent conductive layers, whereby the terms layer, coating, deposit and film are interchangeably used within this invention for a film deposited in vacuum process, be it CVD, LPCVD, plasma enhanced CVD (PECVD) or physical vapour deposition (PVD).

A “deposition environment” according to the present invention shall particularly mean an environment in which a deposition, preferably of zinc oxide, may be performed. For example, a deposition environment may thus comprise, at the stage of deposition, an adequate amount of a suitable precursor. A deposition environment may thereby particularly be the atmosphere being present in a deposition chamber and being in contact with the substrate. According to the invention, with respect to step a) the content of the zinc precursor is thereby especially reduced in the deposition environment to an amount at which deposition of zinc oxide stopps.

The term “solar cell” or “photovoltaic cell”, “PV cell”, comprises in sense of the current invention an electrical component, capable of transforming light, essentially sunlight, directly into electrical energy by means of the photovoltaic effect. A thin film solar cell usually includes a first or front electrode, one or more semiconductor thin film PIN junctions and a second or back electrode, which are successively stacked on a substrate. Each PIN junction or thin film photoelectric conversion unit includes an i-type layer sandwiched between a p-type layer and an n-type layer, whereby “p” stands for positively doped and “n” stands for negatively doped. The i-type layer, which is a substantially intrinsic semiconductor layer, occupies the most part of the thickness of the thin film PIN junction, whereby the photoelectric conversion primarily occurs in this i-type layer.

The term “diborane” as mentioned herein means the commercially available diborane gas mixture of 2% B₂H₆ in hydrogen.

The step of “at least partly” removing the deposition atmosphere from the substrate in the sense of the present invention shall particularly mean that all or at least a significant ratio of the deposition atmosphere of the zinc oxide layer is removed from the substrate. This allows stopping the deposition process. This step may be realized, for example, by guiding gas or a gaseous mixture not containing a precursor being required for the deposition step to the surface of the substrate, or the first layer, respectively. Additionally, or alternatively, this may be performed by reducing the pressure to a certain amount in order to remove the precursor.

The step of “treating” the first zinc oxide layer with the mixture of diborane and water shall particularly mean to bring the surface, preferably the whole surface, of the first zinc oxide layer in contact with the respective compounds. This may be realized by guiding this mixture to the surface of the first zinc oxide layer an allowing an interaction for a sufficient amount of time.

According to an embodiment step b) is accomplished by one or more of the steps comprising
Stopping an inflow of the zinc precursor material into the deposition environment,
Pumping the deposition environment to provide a lower precursor concentration, and/or
Purging the deposition environment by introducing one or more of water, diborane, nitrogen and/or hydrogen.

According to this embodiment, the step of reducing the content of precursor is reduced in the deposition environment, or deposition chamber, respectively, especially to an amount at which the deposition stops. Consequently, the precursor concentration is reduced compared to step a). In detail, this step may preferably be performed by virtue of three steps being possible together or alternatively.

The first possibility is to stop the inflow of the zinc precursor material into the deposition environment. Consequently, the concentration of the precursor will be lowered smoothly.

A further possibility is to pump the deposition environment to provide a lower precursor concentration. In other words, a vacuum, or a reduced pressure, respectively, is applied to the deposition environment thereby reducing the precursor concentration compared to step a).

A further possible step in order to reduce the precursor concentration is to purge the deposition environment by introducing one or more of water, diborane, nitrogen and/or hydrogen. This allows guiding the present precursor out of the deposition environment completely and thus to securely permit a further deposition. Apart from that, especially by introducing water and diborane, step c) may start immediately, making the method according to the invention especially simple and time saving.

According to a further embodiment the step of depositing a first zinc oxide layer within step a) and/or the step of depositing a second zinc oxide layer within step d) is performed by a LPCVD process. This deposition method provides well defined deposition results and may furthermore be performed in a well defined and cost saving manner. Apart from that, inventors have found that growing a second zinc oxide layer stating from new seeds by using LPCVD provides especially good results.

According to a further embodiment the first zinc oxide layer is treated with a mixture of diborane and water in a relation lying in the range of 1:2 to 1:4 in step c). In detail, ratios of 1:2.67 or 1:3.67 are shown to provide sufficient new seeds for starting the growth of the second zinc oxide layer. The deposition of the second zinc oxide layer may thereby be performed in a limited amount of time, being especially suitable for line productions.

According to a further embodiment the mixture of diborane and water is at least partly removed from the substrate before performing step d). This embodiment is particularly preferred if the second zinc oxide layer shall be deposited without being doped or having a low degree of doping only. In detail, by removing especially diborane, a doping may be excluded in contrast whereto a doping may be performed by just leaving the diborane atmosphere, for example, when introducing new precursor gas for coating purposes. Consequently, “at least partly” removing the respective components shall mean a step in which the concentration is sufficiently reduced in order to avoid doping or to only allow it in a desired amount.

According to a further embodiment step a) and step d) are performed in different deposition chambers, and step c) is performed in a further treatment chamber whilst the substrate is delivered from the first deposition chamber to the second deposition chamber. According to this embodiment, a system for LPCVD may be used comprising two deposition chambers. It is then possible to add an additional subsystem between the first and the second deposition chamber. The additional subsystem, which may be formed by an independent gas mixture injection system, for example, may inject a controlled flow of diborane and water in a vacuum chamber, for example. When the substrate is transferred from one deposition chamber to the next, the TCO surface grown in the first chamber is thus treated with a diborane/water mixture, according to step c) of the invention. When TCO growth is continued in the second chamber, new crystals start to grow as described before. This embodiment may be named Inline process with treatment curtain.

Alternatively, two separate machines may be used. The treatment with diborane and water according to step c) may in this case be performed as last step in the first machine, following which the substrate is exposed to air in order to reduce the deposition atmosphere. Afterwards, the deposition is continued in a second machine. Even in this case layer growth restarts from new seeds. The treatment with diborane and water can be performed at the beginning on the deposition in the second machine. Similarly, substrates can be fed to the same machine after a first deposition to receive an additional coating.

In another example, the method according to the invention is performed in more than two deposition chambers. If the deposition system comprises more than two deposition chambers, the treatment subsystem can be placed between any of the deposition chambers. Depending on the number of treatment subsystems and depending on their positions it is possible to achieve discrete thickness ratios between TCO layers. Additionally, tuning the treatment and purging times allows controlling the thickness of the deposited TCO layers. This method may be called multichamber system.

According to a further embodiment the first zinc oxide layer is deposited to have a lower degree of doping compared to the second zinc oxide layer. According to this embodiment, the method according to the invention is particularly suitable for reducing defects in the generated microcrystalline solar cells induced by surface roughness. This advantage may especially be achieved in combination with forming the first zinc oxide layer thicker compared to the second zinc oxide layer.

According to a further embodiment the first zinc oxide layer is deposited to have a higher degree of doping compared to the second zinc oxide layer. According to this embodiment, an especially preferred electrical conductivity and good light scattering properties may be achieved.

According to a further embodiment, at least three layers are subsequently deposited, whereby the layers have a degree of doping being subsequently decreasing from the first zinc oxide layer to the following zinc oxide layers, and steps b) and c) are performed during respective deposition steps. According to this embodiment, reflection losses are prevented especially effective.

According to a further embodiment the first zinc oxide layer is deposited to have an equal degree of doping compared to the second zinc oxide layer. This embodiment allows controlling the surface morphology as well as the optical properties especially effective.

According to a further embodiment at least three zinc oxide layers are subsequently deposited, whereby a middle zinc oxide layer has a degree of doping being smaller compared to the adjacent layers, and steps b) and c) are performed during respective deposition steps. According to this embodiment, volume scattering of light as well as low surface roughness may be adjusted especially effective.

According to a further embodiment the first zinc oxide layer is deposited to have a greater thickness compared to the second zinc oxide layer. This embodiment allows filling the valleys generated at the structure in the first layer. Increasing the number of layers will thereby gradually produce a flatter zinc oxide surface and will lead to a reduction of haze. According to the invention 2 to 8, preferably 1 to 4 TCO layers with an intermediate treatment step according to step c) may be preferred.

Consequently, this embodiment may provide a first TCO layer with large thickness, large average structure size and thus large roughness for light scattering. This layer is similar to the layer depicted on the left frame in FIG. 1. Then an additional TCO layer being thinner than the first layer is grown on top of this first TCO layer. The second layer fills the valleys resulting in a “smoothing out” of the roughness. It is, again, important to point out that the second layer grows from new seeds; it is therefore composed of several small crystallites. This is the key aspect leading to the smoothing effect.

Alternatively, the working principle can be seen as enlarging the characteristic valleys opening angles or an enlarging of the characteristic curvature radius at the valley bottom.

According to a further embodiment the composition and/or temperature is modified during step a) and/or d). With respect to the composition, for example a doping precursor and/or the water/DEZ ratio may be varied. In this embodiment the zinc oxide crystals will continue to grow undisturbed. This approach does not improve the morphology of the TCO layer. However, it can be combined with the treatment according to step c) in order to achieve further degrees of freedom. An example of such a structure is a thick zinc oxide intrinsic layer, followed by a diborane treatment, a thin doped layer and the last ⅓ of deposition again without doping but without treatment according to step c). In this case possible negative effects of boron on the silicon layers are reduced or completely avoided.

Many other embodiments are possible by combining all the above defined steps.

The invention furthermore refers to a solar cell, comprising at least one substrate being coated by a method according to the invention. A solar cell according to the invention essentially provides the advantages described with respect to the method according to the invention. In detail, a solar cell according to the present invention helps to further exploit the remaining potential particularly in the improvement of the light scattering, light trapping, reduction of reflection losses as well as the material quality of thin film silicon layers grown on these substrates.

According to the invention, the solar cell may comprise a front electrode being manufactured by a method according to the invention, and/or it may comprise a so formed back electrode. In case a back electrode, or back contact, respectively, is provided, a doped layer may preferably be followed by an intrinsic layer. This may reduce reflection losses from the back contact and may reduce absorption in the back contact.

### BRIEF DESCRIPTION OF DRAWINGS

These and other aspects of the invention will be apparent from and elucidated with reference to the embodiments described hereinafter.

In the drawings:

FIG. 1 shows zinc oxide layers after different treatment times according to the prior art,

FIG. 2 shows further influences of the treatment times according to the prior art,

FIG. 3 shows a solar cell being the basis for the present invention,

FIG. 4 shows a SEM image of a double structure achieved by a method according to the invention.

FIG. 5 shows spectral haze measurement curves,

FIG. 6 shows the number of defects observed in a microcrystalline silicon cell grown on two different zinc oxide front contacts, and

FIG. 7 shows an enlarged view of a double layer zinc oxide structure produced according to this invention.

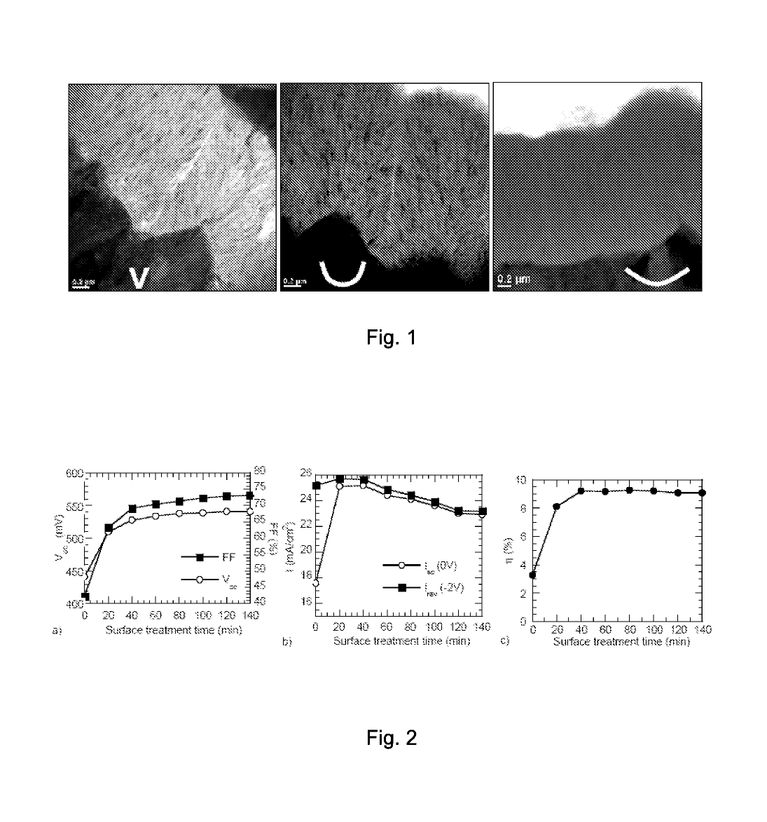

### DETAILED DESCRIPTION OF DRAWINGS

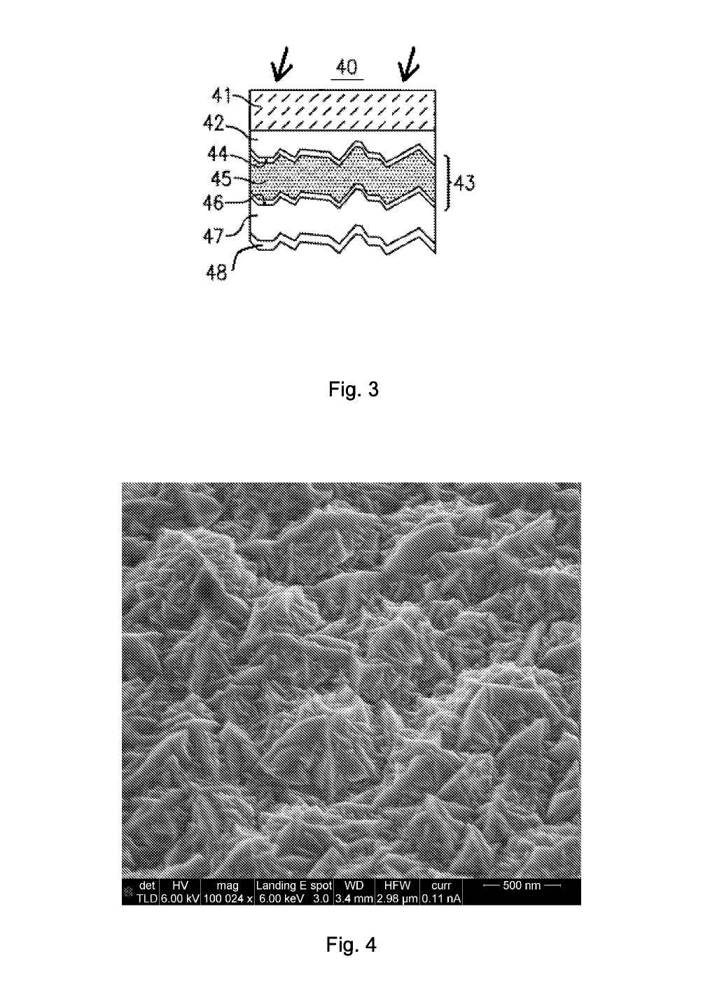

FIG. 3 shows a layout for a thin-film solar cell 40 being generally known from the state of the art and as well being the basis for the present invention. As shown in FIG. 3, the solar cell 40 generally includes a first electrode (layer) 42, one or more semiconductor thin-film p-i-n junctions 43, and a second electrode 47, which are successively stacked on a substrate. Each p-i-n junction 43 or thin-film photoelectric conversion unit includes an i-type layer 45 sandwiched between a p-type layer 44 and an n-type layer 46 (p-type=positively doped, n-type=negatively doped). The i-type layer 45, which is a substantially intrinsic semiconductor layer, occupies the most part of the thickness of the thin-film p-i-n junction. Photoelectric conversion occurs primarily in this i-type layer. The electrode layers 42, 47 are responsible for collecting the photovoltaically generated electric current. The electrodes have to cope with three major challenges: High conductivity, good transparency and ability to scatter the light into the adjacent photoactive layers (haze). A backreflector layer 48 may help to re-reflect not absorbed light in the direction of the absorber layer. In FIG. 3 arrows indicate the light originally impinging on substrate 41.

An optically transparent and electrically conductive front electrode 42 is—as mentioned above—a fundamental part of thin film solar cells 40. A high efficiency of the solar cell 40 is strongly depending on low parasitic optical losses, a complete absorption in the photoactive layer and a complete extraction of the photo-generated charge carriers. The front electrode 42 has therefore to provide for a high optical transparency in combination with good electrical conductivity and a rough surface morphology which introduces light scattering. Light scattering is essential for trapping of the light inside the solar cell device, since it extends the way of the light in the absorbing silicon layers; in other words improves the probability of the light being absorbed.

In order to improve a solar cell according to the invention, the substrate 41 should be coated with a TCO-layer, in particular with a zinc oxide layer. The method of coating a substrate (41) for manufacturing a solar cell (40) in a deposition environment according to the invention comprises the following steps:

a) Depositing a first zinc oxide layer onto a substrate (41),

b) Reducing a zinc precursor content in the deposition environment,

c) Treating the first zinc oxide layer with a mixture of diborane and water to form a plurality of coating seeds on the surface of the first zinc oxide layer, and

d) Depositing a second zinc oxide layer onto the first zinc oxide layer.

An exemplary performance of the method according to the invention is as follows. Like stated above the method according to the invention comprises a procedure to restart growth of a zinc oxide layer on a previously deposited zinc oxide layer. In this example, the method is based on a glass substrate having a dimension of 1.4 m² in a conventional low pressure chemical vapour deposition process environment. It is furthermore based on treating the first zinc oxide layer with diborane in step c) and may thus be named hereinafter “Diborane treatment”. This exemplary method comprises the following steps.

The first step comprises to stop the DEZ (diethylzinc, precursor material of ZnO deposition) flow in the process chamber, or deposition chamber, respectively. Other process gases like diborane, water, nitrogen or hydrogen may be stopped as well.

A further step includes reducing the DEZ concentration in the deposition chamber by pumping or purging. A pumping step may particularly comprise to reduce the pressure inside the chamber to a pressure of approx. ½ of the usual process pressure or less, i.e. at least 0.2 mbar, for example in the range of 0.2 mbar to 0.1 mbar. Depending on the performance of the installed pumps, the pumping time will be around 60 s or less. Alternatively, any remaining DEZ from previous process steps may be removed by purging the chamber using other process gases, such as diborane, water, hydrogen, nitrogen, or another inert gas, etc. Purging for 60 s with 400 sccm water has been shown to be sufficient. Larger purging gas flows allow shortening this step.

A further step includes introducing diborane and water into the process chamber, or deposition chamber, respectively, where the substrate is located. A successful treatment for a commercially available TCO 1200 system (Oerlikon Solar) for 1.4 m² substrates uses 550 sccm water, 150 sccm diborane for one single treatment chamber, plus optionally hydrogen. Exposure of the substrate to said gas mixture for at least 30 seconds, for example for at least 60 seconds is sufficient. A quicker treatment suitable for production uses 1000 sccm water and 375 sccm diborane. In this case only 15 s are necessary to achieve a successful treatment. Experiments have shown that a treatment of several minutes such as in a range of 15 min to 20 min is possible, for economic reasons however it may be preferred to limit the duration of the treatment. Generally, treatment times of 5 s to 20 min, for example from 15 s to 5 min may be preferred. In a further embodiment an exposure ratio of 90-120, preferably 110 sccm diborane/m² exposed zinc oxide surface established for 30 seconds. In a further embodiment the ratio of diborane gas flow per exposed surface area times treatment time is being kept essentially constant.

It is to be noted that this step does not produce a new layer. Measurement shows that small islands or particles, such as most likely boron oxide, are formed on the TCO surface, but not a complete layer. Treatments with less diborane may work as well. However, it might then be necessary to increase the treatment time. Similarly, larger diborane flows may further reduce the treatment time. The process pressure is usually like known for conventional zinc oxide deposition steps and thus in a range of 0.1 to 1 mbar. The process temperature is not changed from the one used for conventional zinc oxide deposition being used in a previous step.

It is furthermore possible to just purge the deposition chamber with the diborane/water mixture specified above for a longer time instead of removing the deposition atmosphere and purge the deposition chamber like described above. It is just important to reduce the amount of DEZ to stop the zinc oxide growth.

In a further step, after the diborane treatment, again, the process chamber may be purged like described above. This step is especially recommended if the successive layer should be deposited without any diborane doping, otherwise it can be skipped.

Subsequently, the growth of a second zinc oxide layer is started by providing a process environment like described above. The process environment may thereby be the same like known in the art for conventional LPCVD processes for depositing zinc oxide.

As an example, a deposition sequence for a zinc oxide layer stack comprises the steps of depositing a first layer of zinc oxide exhibiting a first surface texture, treating the surface of said first layer with a gas mixture comprising diborane but no zinc-component without depositing a layer and then depositing a second layer of zinc oxide exhibiting a surface texture with smaller features than said first surface texture.

As a consequence of the above defined method, the growth of the second zinc oxide layer will start independently of the underlying first zinc oxide layer. Based on this procedure it thus becomes possible to produce predefined sequences of zinc oxide layers each with different properties including roughness, average structure size and refractive index.

Examples of possible structures include the following:

As first example, at least one doped zinc oxide layer (e.g. flow ratio 1/0.5 DEZ/Diborane, alternatively 1/0.1) on top of an intrinsic (or low doped) zinc oxide layer may be provided. One successful realization is shown in FIG. 4. In the example shown, the thickness ratio was 1 (doped) to 6 (intrinsic), even ratios of 1 to 4 may be effective. Similar layer sequences are suitable for reducing defects in microcrystalline solar cells 40 induced by surface roughness. Optimization of the thickness ratio and doping levels is mandatory to adjust conductivity, transparency, feature size, light scattering and influence on silicon growth. A possible realization includes one comparatively thick intrinsic (or low doped) zinc oxide layer followed by two or more thinner and more doped zinc oxide layers. A treatment as described in this invention according to step c) is performed between each layer. This realization allows filling the valleys in the first layer. Increasing the number of layers will gradually produce a flatter zinc oxide surface and will lead to a reduction of haze. According to the invention 2 to 8, preferably 1 to 4 TCO layers with an intermediate treatment step according to the invention are being proposed.

As a further example, intrinsic layers on top of low doped layers may be provided. In this case, the low doped layers (exemplary flow ratios: 1/1.2/0.01 H₂O/DEZ/B₂H₆, 700 s) provide an acceptable electrical conductivity and a good light scattering. The additional intrinsic layer (exemplary flow ratios: 1/1.2/0 H₂O/DEZ/B₂H₆, 100 s), which has a larger refractive index than the underlying doped layer is useful in reducing the light reflections at the TCO/Silicon interface. Using this approach it is possible to increase the current produced in a later photovoltaic device.

As a further example, two zinc oxide layers of nominally same doping level can be grown one on the other. In this case it is again possible to control the surface morphology and the optical properties.

As a further example, three or more layers with a decreasing doping level, leading to an increasing refractive index, may be provided. This approach reduces reflection even further. Light scattering can be optimized by tuning the thickness of each layer.

As a further example, three layer stacks with low doping/high doping/low doping layers may be provided. This kind of system should allow achieving volume scattering of light and low surface roughness.

Referring back to FIG. 4, this figure shows a SEM image of the novel double structure. In detail, FIG. 4 shows a SEM picture of a doped (flow ratio 1/1.1/0.3 H₂O/DEZ/B₂H₆, 960 s) zinc oxide layer on an intrinsic layer (flow ratio 1/1.1/0 H₂O/DEZ/B₂H₆, 160 s). It is clearly possible to see small structures growing on larger structures.

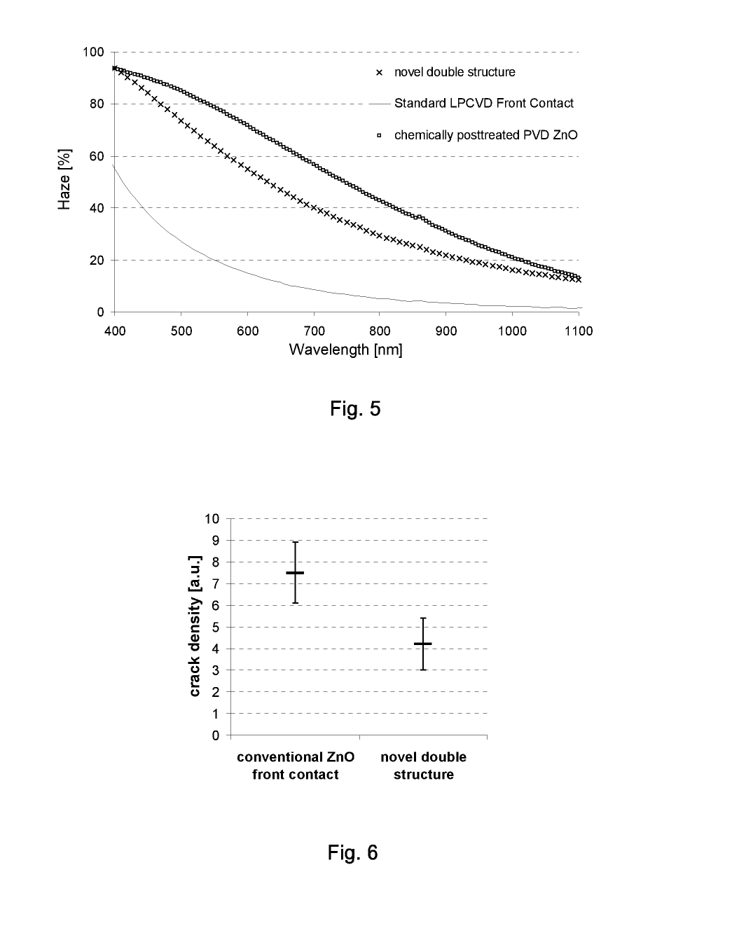

FIG. 5 shows spectral haze measurement curves of the novel double structure in comparison with a typical zinc oxide single layer and a post treated front electrode based on PVD zinc oxide layer. In detail, FIG. 5 shows a spectral haze measurement for the same structures compared to other substrates. It may be seen that the haze lies in a range between the standard procedure of a LPCVD front contact and a chemically posttreated zinc oxide layer being deposited by PVD.

FIG. 6 shows the effect of using the same structure on the number of defects observable in a microcrystalline silicon cell. The double layer zinc oxide front contacts allow to gain haze and to reduce the number of defects. In detail, FIG. 6 shows details of the number of defects observed in a microcrystalline silicon cell grown on two different zinc oxide front contacts. On the left side, the cell was grown on a standard single layer zinc oxide. On the right side, the cell was grown on double layer zinc oxide front contact (depicted in FIG. 4) prepared according to the method according to the present invention. The number of defects is clearly reduced, thus improving the quality of the solar cell 40.

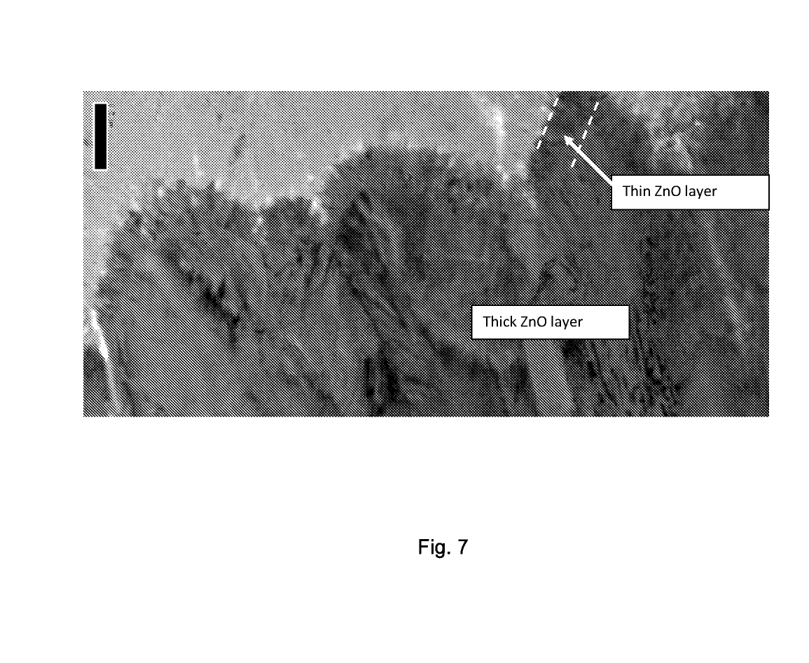

FIG. 7 shows an enlarged view of a double layer zinc oxide structure produced according to this invention and thus details of double layer TCO. The STEM picture according to FIG. 7 shows a thin zinc oxide layer grown on top of a thicker zinc oxide layer. For better understanding the layer structure, the dashed line highlight the thin addition zinc oxide layer grown according to this invention. The scale bar in the top left corner corresponds to 200 nm. It is possible to see two distinct zinc oxide layers with slightly different contrast. A contrast difference may originate from a difference in density of the additional zinc oxide layer, different doping etc. This picture has been measured by STEM (Scanning Transmission Electron Microscope) system and cutting a thin section of TCO/Si layers using a FIB (Focused Ion Beam) system. Similar images can be produced using a TEM (Transmission Electron Microscope). Sample preparation can be done by FIB or by mechanical cutting and successive polishing of a suitable sample.

While the invention has been illustrated and described in detail in the drawings and foregoing description, such illustration and description are to be considered illustrative or exemplary and not restrictive; the invention is not limited to the disclosed embodiments. Other variations to be disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting scope.

Reference Signs List

| | |
|---|---|
| 40 | solar cell |
| 41 | substrate |
| 42 | electrode layer |
| 43 | p-i-n junction |
| 44 | p-type-layer |
| 45 | i-type-layer |
| 46 | n-type-layer |
| 47 | electrode layer |
| 48 | backreflector layer |

1. Method of coating a substrate (41) in a deposition environment for manufacturing a solar cell (40), the method comprising the steps of:
a) Depositing a first zinc oxide layer onto a substrate (41),
b) Reducing a zinc precursor content in the deposition environment,
c) Treating the first zinc oxide layer with a mixture of diborane and water to form a plurality of coating seeds on the surface of the first zinc oxide layer, and
d) Depositing a second zinc oxide layer onto the first zinc oxide layer.

2. Method according to claim 1, whereby step b) is accomplished by one or more of the steps comprising
Stopping an inflow of the zinc precursor material into the deposition environment,
Pumping the deposition environment to provide a lower precursor concentration, and/or
Purging the deposition environment by introducing one or more of water, diborane, nitrogen and/or hydrogen.

3. Method according to claim 1, whereby the step of depositing a first zinc oxide layer within step a) and/or the step of depositing a second zinc oxide layer within step d) is performed by a LPCVD process.

4. Method according to claim 1, whereby the first zinc oxide layer is treated with a mixture of diborane and water in a relation lying in the range of 1:2 to 1:4 in step c).

5. Method according to claim 1, whereby the mixture of diborane and water is at least partly removed from the substrate (41) before performing step d).

6. Method according to claim 1, whereby step a) and step d) are performed in different deposition chambers, and whereby step c) is performed in a further treatment chamber whilst the substrate (41) is delivered from the first deposition chamber to the second deposition chamber.

7. Method according to claim 1, whereby the first zinc oxide layer is deposited to have a lower degree of doping compared to the second zinc oxide layer.

8. Method according to claim 1, whereby the first zinc oxide layer is deposited to have a higher degree of doping compared to the second zinc oxide layer.

9. Method according to claim 1, whereby at least three layers are subsequently deposited, whereby the layers have a degree of doping being subsequently decreasing from the first zinc oxide layer to the following zinc oxide layers, and whereby steps b) and c) are performed during respective deposition steps.

10. Method according to claim 1, whereby the first zinc oxide layer is deposited to have an equal degree of doping compared to the second zinc oxide layer.

11. Method according to claim 1, whereby at least three zinc oxide layers are subsequently deposited, whereby a middle zinc oxide layer has a degree of doping being smaller compared to the adjacent layers, and whereby steps b) and c) are performed during respective deposition steps.

12. Method according to claim 1, whereby the first zinc oxide layer is deposited to have a greater thickness compared to the second zinc oxide layer.

13. Method according to claim 1, whereby the composition and/or temperature is modified during step a) and/or d).

14. Solar cell, comprising at least one substrate (41) being coated by a method according to claim 1.
